(19) United States
(12) Patent Application Publication
(10) Pub. No.: US 2008/0013278 A1
(43) Pub. Date: Jan. 17, 2008

(54) Reservoir for liquid cooling systems used to provide make-up fluid and trap gas bubbles

(76) Inventors: Fredric Landry, Montreal (CA); Bruce R. Conway, La Honda, CA (US); Richard Grant Brewer, Foster City, CA (US); Norman Chow, Milpitas, CA (US); Peng Zhou, Albany, CA (US); Tien-Chih (Eric) Lin, Fremont, CA (US)

Correspondence Address: HAVERSTOCK & OWENS LLP, 162 N WOLFE ROAD, SUNNYVALE, CA, 94086, US

(21) Appl. No.: 11/823,525

(22) Filed: Jun. 27, 2007

Related U.S. Application Data
(60) Provisional application No. 60/817,855, filed on Jun. 30, 2006.

(51) Int. Cl. H05K 7/20

(52) U.S. Cl. 361/699

(57) ABSTRACT

A fluid compensation apparatus is configured to provide replacement fluid to a fluid-based cooling loop, while removing dissolved gas or gas in gross bubbles from the cooling loop. Removal or reduction of gas from the cooling loop reduces or prevents pump vapor lock. The removed gas is retained within the fluid compensation apparatus. The fluid compensation apparatus is configured to prevent the trapped gas from being re-introduced to the fluid-based cooling loop, regardless of the orientation of the fluid compensation apparatus. Additionally, the fluid compensation apparatus is configured to remove gas from and add fluid to the cooling loop with limited or no pressure drop between the inlet port and the outlet port of the fluid compensation apparatus. As a result, the pump does not require additional power to compensate for such a pressure differential.

### RELATED APPLICATIONS

This Patent Application claims priority under 35 U.S.C. 119 (e) of the co-pending U.S. Provisional Patent Application, Ser. No. 60/817,855 filed Jun. 30, 2006, and entitled “MULTI-STAGE STAGGERED RADIATOR FOR HIGH PERFORMANCE LIQUID COOLING APPLICATIONS”. The Provisional Patent Application, Ser. No. 60/817,855 filed Jun. 30, 2006, and entitled “MULTI-STAGE STAGGERED RADIATOR FOR HIGH PERFORMANCE LIQUID COOLING APPLICATIONS” is also hereby incorporated by reference.

### FIELD OF THE INVENTION

The invention relates to a cooling loop for cooling a heat producing device in general, and specifically, to a fluid reservoir used in liquid cooling applications.

### BACKGROUND OF THE INVENTION

Cooling of high performance integrated circuits with high heat dissipation is presenting significant challenge in the electronics cooling arena. Conventional cooling with heat pipes and fan mounted heat sinks are not adequate for cooling chips with every increasing wattage requirements.

A particular problem with cooling integrated circuits within personal computers is that more numerous and powerful integrated circuits are configured within the same size or small personal computer chassis. As more powerful integrated circuits are developed, each with an increasing density of heat generating transistors, the heat generated by each individual integrated circuit continues to increase. Further, more and more integrated circuits, such as graphics processing units, microprocessors, and multiple-chip sets, are being added to personal computers. Still further, the more powerful and more plentiful integrated circuits are being added to the same, or small size personal computer chassis, thereby increasing the per unit heat generated for these devices. In such configurations, conventional personal computer chassis' provide limited dimensions within which to provide an adequate cooling solution. Conventionally, the integrated circuits within a personal computer are cooled using a heat sink and a large fan that blows air over the heat sink, or simply by blowing air directly over the circuit boards containing the integrated circuits. However, considering the limited free space within the personal computer chassis, the amount of air available for cooling the integrated circuits and the space available for conventional cooling equipment, such as heat sinks and fans, is limited.

Closed loop liquid cooling presents alternative methodologies for conventional cooling solutions. Closed loop liquid cooling solutions more efficiently reject heat to the ambient than air cooling solutions. A closed loop cooling system includes a cold plate to receive heat from a heat source, a radiator with fan cooling for heat rejection, and a pump to drive fluid through the closed loop. The design of each component is often complex and requires detailed analysis and optimization for specific applications. A conventional cooling loop suffers from loss of fluid over time, primarily due to permeation. To replenish lost fluid, a fluid reservoir is often included in the cooling loop.

FIG. 1 illustrates a cut-out side view of a conventional fluid reservoir tank 2. The fluid reservoir tank 2 includes an inlet port 5 coupled to an inlet fluid line 7 and an outlet port 6 coupled to an outlet fluid line 8. The inlet fluid line 7 and the outlet fluid line 8 are part of a fluid-based cooling loop. The fluid reservoir tank 2 stores excess fluid 4. Fluid flowing through the cooling loop enters the fluid reservoir tank 2 via the inlet port 5 and outputs via the outlet port 6. Such a configuration suffers from an increased pressure differential between the inlet port 5 and the outlet port 6 of the fluid reservoir tank 2, as fluid entering the fluid reservoir tank 2 decelerates relative to the fluid flowing in the inlet fluid line 7, and fluid exiting the liquid reservoir tank 2 via the outlet port 6 and entering the output fluid line 8 is accelerated relative to the fluid in the fluid reservoir tank 2. The resulting pressure differential between the inlet port 5 and the outlet port 6 of the liquid reservoir tank 2 requires additional pumping power in the cooling loop to compensate.

Problems also occur when such a fluid reservoir tank is not oriented properly. As the cooling loop loses liquid and the fluid reservoir adds fluid to the cooling loop, gas begins to accumulate in the fluid reservoir tank as a gas pocket, such as gas pocket 3 in FIG. 1. If the fluid reservoir tank is improperly oriented, the gas pocket can become positioned at the outlet port, thereby introducing gas into the cooling loop. This can pose a danger to systems using a centrifugal pump, in that if a large gas bubble accumulates volume in the system, then breaks free, it can cause the pump to “vapor lock”, which essentially traps gas in the pump and prevents it from pumping fluid. Even if oriented correctly, pump failure can still occur due to gas accumulation in the cooling loop that does not get extracted into the fluid reservoir tank.

Conventionally, there have been two main methods to combat this problem. First, the fluid reservoir tank is configured as a large open tank, with an inlet and an outlet. The problem with this configuration is pressure drop as described above, where the fluid velocity is significantly reduced upon entering the fluid reservoir tank and significantly increased upon exiting. The pump must work harder to make the fluid regain momentum at the outlet of the reservoir tank. Second, the fluid reservoir tank is pressurized. In this configuration, gas is minimized by pressurizing the fluid lines within the cooling loop, thereby preventing gas migration into the loop from the fluid reservoir tank. The problem with this configuration is an increase in complexity.

What is needed is a more efficient methodology and apparatus for adding liquid to a cooling loop. What is also needed is an efficient methodology for removing air bubbles from within a cooling loop.

### SUMMARY OF THE INVENTION

The fluid compensation apparatus is configured to provide replacement fluid, also referred to as volume compensation, to a fluid-based cooling loop, while removing dissolved gas or gas in gross bubbles from the cooling loop. Removal or reduction of gas from the cooling loop reduces or prevents pump vapor lock. The removed gas is retained within the fluid compensation apparatus. In some embodiments, the fluid compensation apparatus is configured to prevent the trapped gas from being re-introduced to the fluid-based cooling loop, regardless of the orientation of the fluid compensation apparatus.

Additionally, the fluid compensation apparatus is configured to remove gas from and add fluid to the cooling loop with limited or no pressure drop between the inlet port and the outlet port of the fluid compensation apparatus. As a result, the pump does not require additional power to compensate for such a pressure differential.

In one aspect, a fluid compensation apparatus includes a fluid reservoir tank including an inlet port and an outlet port, wherein the fluid reservoir tank is configured to store fluid, an inlet fluid line coupled to the inlet port and configured to input fluid into the inlet port, an outlet fluid line coupled to the outlet port and configured to output fluid from the outlet port, and a bridging fluid line coupling the inlet port to the outlet port, wherein the bridging fluid line is configured to pass input fluid from the inlet port to the outlet port, further wherein the bridging fluid line includes one or more exchange vents, thereby exposing the fluid in the bridging fluid line to the fluid in the fluid reservoir tank, each of the one or more exchange vents is configured to enable gas present in the bridging fluid line to pass into the fluid reservoir tank and to enable fluid in the fluid reservoir tank to pass into the bridging fluid line. A size of each of the one or more exchange vents, a surface tension of the fluid in the bridging fluid line, and a fluid flow rate of the fluid in the bridging fluid line can be configured to substantially prevent the fluid in the bridging fluid line from passing through the one or more exchange vents. A size of each of the one or more exchange vents, a surface tension of the fluid in the bridging fluid line, and a fluid flow rate of the fluid in the bridging fluid line can be configured to enable gas present in the bridging fluid line to pass through the one or more exchange vents and into the fluid reservoir tank. A size of each of the one or more exchange vents, a surface tension of the fluid in the bridging fluid line, and a fluid flow rate of the fluid in the bridging fluid line can be configured to substantially prevent gas accumulated in the fluid reservoir tank from passing through the one or more exchange vents and into the bridging fluid line. The fluid reservoir tank can be configured such that gas accumulated in the fluid reservoir tank is not exposed to the bridging fluid line. The fluid reservoir tank can be orientation-independent. The fluid reservoir tank can be orientation-specific. Each of the one or more exchange vents can be a hole, slit, or perforation. Each of the one or more exchange vents can be a mesh. The gas present in the bridging fluid line can be gas bubbles or soluble gas. The fluid reservoir tank can be sealed. The fluid reservoir tank can be configured to be opened. The fluid compensation apparatus can be coupled to a fluid-based cooling loop, where the cooling loop is configured to provide fluid to and from the fluid compensation apparatus.

In another aspect, a fluid compensation apparatus includes a fluid reservoir tank including an access opening, wherein the fluid reservoir tank is configured to store fluid, an extension coupled to the access opening, and a bridging fluid line coupled to the extension, wherein the bridging fluid line is configured to pass fluid therethrough, further wherein the bridging fluid line includes one or more exchange vents and is coupled to the extension such that the one of more exchange vents are exposed to fluid in the fluid reservoir tank via the extension, each of the one or more exchange vents is configured to enable gas present in the bridging fluid line to pass into the fluid reservoir tank and to enable fluid in the fluid reservoir tank to pass into the bridging fluid line. A size of each of the one or more exchange vents, a surface tension of the fluid in the bridging fluid line, and a fluid flow rate of the fluid in the bridging fluid line can be configured to substantially prevent the fluid in the bridging fluid line from passing through the one or more exchange vents. A size of each of the one or more exchange vents, a surface tension of the fluid in the bridging fluid line, and a fluid flow rate of the fluid in the bridging fluid line can be configured to enable gas present in the bridging fluid line to pass through the one or more exchange vents and into the fluid reservoir tank. A size of each of the one or more exchange vents, a surface tension of the fluid in the bridging fluid line, and a fluid flow rate of the fluid in the bridging fluid line can be configured to substantially prevent gas accumulated in the fluid reservoir tank from passing through the one or more exchange vents and into the bridging fluid line. The fluid reservoir tank can be configured such that gas accumulated in the fluid reservoir tank is not exposed to the bridging fluid line. Each of the one or more exchange vents can be a hole, slit, or perforation. Each of the one or more exchange vents can be a mesh. The gas present in the bridging fluid line can be gas bubbles or soluble gas. The fluid reservoir tank can be sealed. The fluid reservoir tank can be configured to be opened. The fluid reservoir tank can include more than one access opening and the fluid compensation apparatus comprises one or more extensions configured to couple the fluid reservoir tank to the bridging fluid line.

Other features and advantages of the present invention will become apparent after reviewing the detailed description of the embodiments set forth below.

### BRIEF DESCRIPTION OF THE DRAWINGS

FIG. 1 illustrates a cut-out side view of a conventional fluid reservoir tank.

FIG. 2 illustrates a schematic block diagram of an exemplary fluid-based cooling loop.

FIG. 3 illustrates a cut-out side view of an exemplary configuration of the fluid reservoir in FIG. 2.

FIG. 4 illustrates a plurality of vents configured longitudinally along the relative top surface of the bridging fluid line.

FIG. 5 illustrates a plurality of vents configured radially around the bridging fluid line.

FIG. 6 illustrates a plurality of vents configured both longitudinally along and radially around the bridging fluid line, where the plurality of vents are longitudinally aligned.

FIG. 7 illustrates a plurality of vents configured both longitudinally along and radially around the bridging fluid line, where the plurality of vents are longitudinally staggered.

FIG. 8 illustrates an exemplary configuration of the bridging fluid line including a mesh.

FIG. 9 illustrates a cut-out side vies of an exemplary configuration of an orientation-independent fluid reservoir tank and bridging fluid line.

FIG. 10 illustrates a cut-out side view of an exemplary alternative configuration of a fluid reservoir tank coupled to an external bridging fluid line.

The present invention is described relative to the several views of the drawings. Where appropriate and only where identical elements are disclosed and shown in more than one drawing, the same reference numeral will be used to represent such identical elements.

### DETAILED DESCRIPTION OF THE PRESENT INVENTION

Embodiments of the present invention are directed to a fluid compensation apparatus for adding fluid to a fluid-based cooling loop and for removing air bubbles from within the cooling loop. The cooling loop is included within a cooling system, where the cooling system removes heat generated by one or more heat generating devices within an electronics system, such as a personal computer. The heat generating devices include, but are not limited to, one or more central processing units (CPU), a chipset used to manage the input/output of one or more CPUs, one or more graphics processing units (GPUs), and/or one or more physics processing units (PPUs), mounted on a motherboard, a daughter card, and/or a PC expansion card. The cooling system can also be used to cool power electronics, such as mosfets, switches, and other high-power electronics requiring cooling. In general, the cooling system described herein can be applied to any electronics sub-system that includes a heat generating device to be cooled. The cooling system is preferably configured within a personal computer chassis. Alternatively, the cooling system is configured as part of any electronics system that includes heat generating devices to be cooled. The cooling loop includes a fluid reservoir, a pump, a heat rejector, and one or more heat exchangers. The components in the cooling loop are coupled via flexible fluid lines.

The fluid compensation apparatus includes a fluid reservoir tank and a bridging fluid line. The fluid reservoir tank has a fluid inlet port and a fluid outlet port. The bridging fluid line couples the inlet port and the outlet port of the fluid reservoir tank. The bridging fluid line is configured with one or more exchange vents, which are openings in the bridging fluid line that allow the exchange of gas and fluid between the reservoir fluid tank and the fluid in the cooling loop of which the reservoir is a part of.

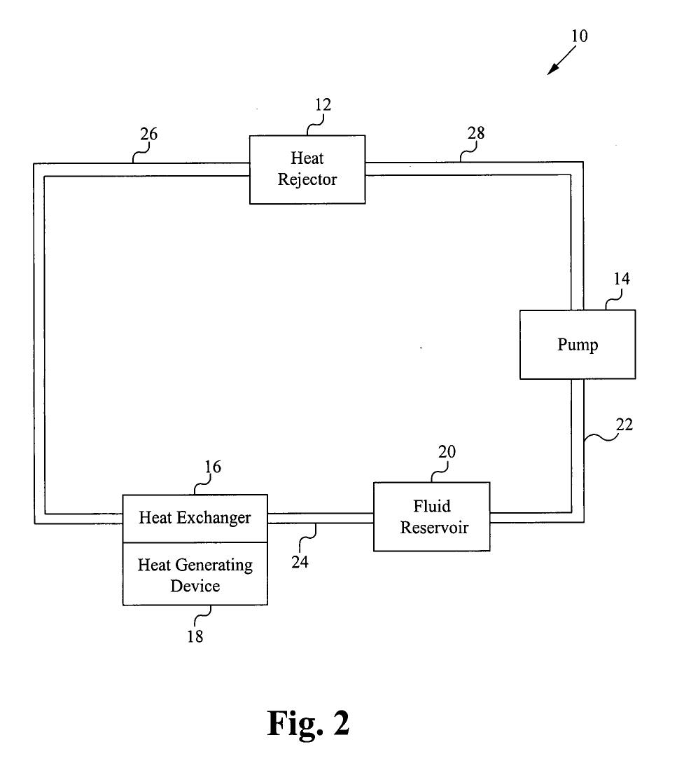

FIG. 2 illustrates a schematic block diagram of an exemplary fluid-based cooling loop 10 which includes a heat exchanger 16, a heat rejector 12, a pump 14, and a fluid reservoir 20, coupled via fluid lines 22, 24, 26, 28. The heat exchanger 16 is thermally coupled to a heat generating device 18. The pump 14 pumps and circulates fluid within the closed loop 10. Heat generated by the heat generating device 18 is passed to the fluid flowing through the heat exchanger 16.

The fluid compensation apparatus collects gas in a fluid reservoir tank, while minimizing a pressure drop across the fluid reservoir tank. The additional benefit of this design is that vented gas is trapped in a way that prevents the gas from being re-introduced to the cooling loop. In some embodiments, the gas is prevented from being re-introduced to the cooling loop regardless of the orientation of the reservoir tank and the internal components thereof.

The exchange vents in the bridging fluid line allow gas bubbles to migrate into the fluid reservoir tank via buoyancy, thus replacing the displaced gas with additional working fluid, thereby preventing the buildup of gas in the system that can lead to pump vapor lock. The vents through which gas is exchanged for fluid can be either a single vent or a plurality of vents. There is a preferred vent size that allows for the exchange of gas that is dependent on the working pressure within the fluid reservoir tank, the fluid velocity through the bridging fluid line, and the fluid surface tension. In general, gas bubbles within the fluid have a certain size. The size is determined by the specific fluid characteristics. The size of the vents is optimized according to the size of the gas bubbles and to a maximum velocity of the fluid through the bridging fluid line. The maximum velocity of the fluid, relative to the size of the gas bubbles and the size of the vents, can not be so great that the gas bubbles pass by the vents without exiting. The shape of the vents can also be determined according to the aforementioned factors.

In some embodiments, the operating parameters are optimized so as to prevent fluid within the bridging fluid line from exiting the vents. Such a configuration is particularly useful when the fluid reservoir tank is not oriented properly and the bridging fluid line is exposed to gas pocket within the fluid reservoir tank. In such a case, the fluid surface tension, the size of the vents, and the fluid velocity are configured such that gas from within the fluid reservoir tank, yet external to the bridging fluid line, does not enter the bridging fluid line, and the fluid flow through the bridging fluid line without exiting the vents. In this case, the size of the vents must be small enough and the surface tension of the fluid must be great enough to prevent gas from re-entering into the fluid line. The linear velocity of the fluid through the bridging fluid line also plays a factor in this determination.

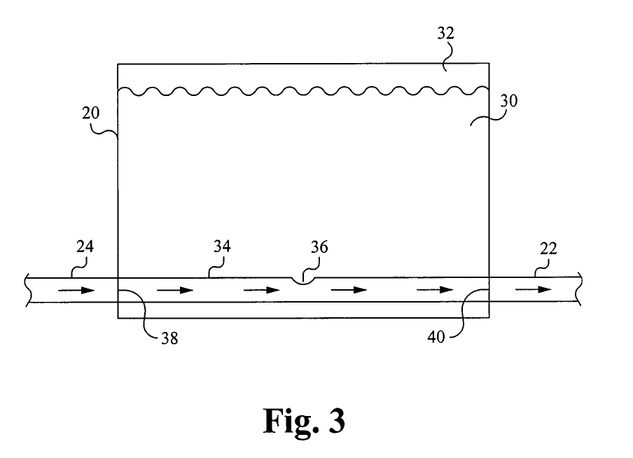

FIG. 3 illustrates a cut-out side view of an exemplary configuration of the fluid reservoir tank 20 in FIG. 2. The fluid reservoir tank 20 includes an inlet port 38 coupled to the inlet fluid line 24 and an outlet port 40 coupled to the outlet fluid line 22. A bridging fluid line 34 is configured within the fluid reservoir tank 20 and couples the inlet port 38 to the outlet port 40. The fluid reservoir tank 20 stores excess fluid 30. Fluid flowing through the cooling loop enters the fluid reservoir tank 20 via the inlet port 38, flows through the fluid reservoir tank 20 via the bridging fluid line 34, and outputs the fluid reservoir tank 20 via the outlet port 40. As fluid flows through the fluid line 34, gas within the fluid exit the bridging fluid line 34 via one or more vents 36. A cross-sectional area of the bridging fluid line 34 is preferably the same or similar to the cross-sectional area of the inlet fluid line 24 and the cross-sectional area of the outlet fluid line 22.

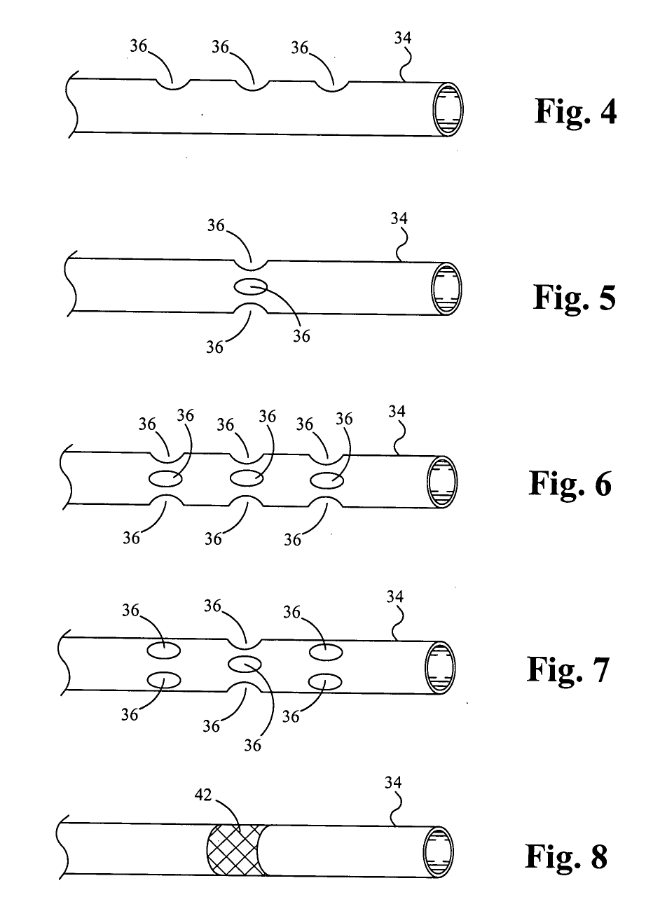

Each vent 36 is an opening, such as a hole, slit, or perforation, in the bridging fluid line 34 that allows the exchange of gas for fluid between the cooling loop and the fluid reservoir tank. The bridging fluid line 34 can be configured with any number of vents 36. For example, FIG. 3 illustrates the bridging fluid line 34 with a single vent 36 configured on a relative top surface of the bridging fluid line 34. Alternatively, the single vent can be configured at any position on the bridging fluid line 34. FIG. 4 illustrates a plurality of vents configured longitudinally along the relative top surface. FIG. 5 illustrates a plurality of vents configured radially around the bridging fluid line 34. FIG. 6 illustrates a plurality of vents configured both longitudinally along and radially around the bridging fluid line, where the plurality of vents are longitudinally aligned. FIG. 7 illustrates a plurality of vents configured both longitudinally along and radially around the bridging fluid line, where the plurality of vents are longitudinally staggered. It is understood that other vent configurations are also contemplated. Radially configuring the bridging fluid line with vents frees the fluid reservoir tank from having to be specifically oriented in order for the gas within the bridging fluid line to exit the vents into the fluid reservoir tank. Positioning vents radially about the bridging fluid line makes the fluid reservoir tank orientation independent in this respect.

In some embodiments, the vents are replaced by one or more mesh portions. FIG. 8 illustrates an exemplary configuration of the bridging fluid line 34 including a mesh 42. Each mesh portion can be configured to partially or completely, as in FIG. 8, encircle the bridging fluid line. In general, the bridging fluid line is configured with one or more openings to allow air bubbles within the bridging fluid line to exit through the one or more openings into the fluid reservoir and to allow fluid within the fluid reservoir to enter the bridging fluid line.

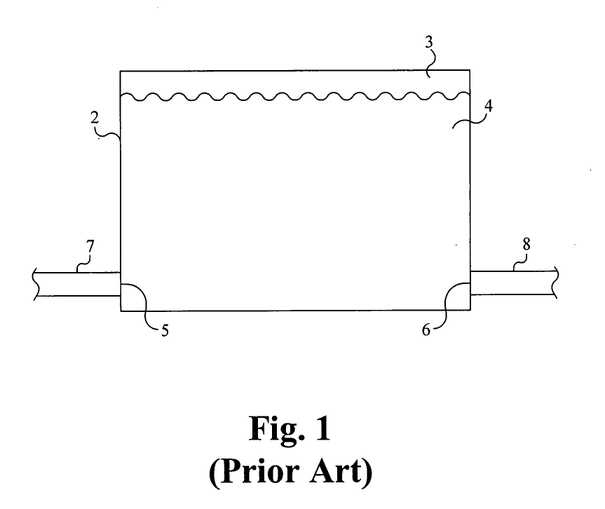

Depending on the application of the cooling loop, the fluid reservoir tank can be configured for one or more specific orientations, or the fluid reservoir can be configured to be orientation independent. For example, a desktop computer is typically fixed in position and rarely if ever moved, particularly in operation. The fluid reservoir tank in this application can be configured similarly to that of FIG. 1, where the gas pocket 32 accumulates at a top portion of the fluid reservoir tank and the bridging fluid line is configured near the bottom of the fluid reservoir tank. In this application, it is not anticipated that the fluid reservoir tank is inverted, such as if the desktop computer is operated upside down, thereby avoiding the situation where the exchange vents in the bridging fluid line is exposed to the gas pocket. In another example, a laptop computer is used in any one of numerous different positions. The fluid reservoir tank in this application can be configured as orientation-independent, where the exchange vents in the bridging fluid line are not exposed to the gas pocket regardless of the orientation of the fluid reservoir tank. In alternative applications, the fluid reservoir tank, the position of the bridging fluid line within the fluid reservoir tank, and the position of the exchange vents on the bridging fluid line can be configured for multiple orientations, for example more than one orientation but not entirely orientation-independent.

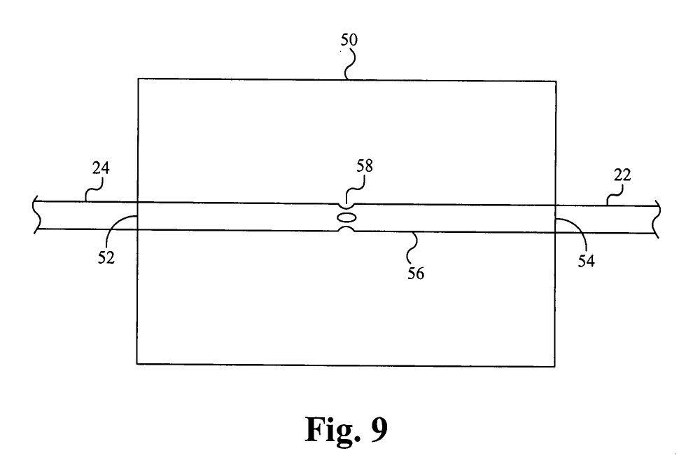

FIG. 9 illustrates a cut-out side vies of an exemplary configuration of an orientation-independent fluid reservoir tank and bridging fluid line. In this exemplary configuration, a bridging fluid line 56 is positioned substantially along a center axis of a fluid reservoir tank 50. The fluid reservoir tank 50 includes an inlet port 52 coupled to the inlet fluid line 24, and an outlet port 54 coupled to the outlet fluid line 22. The bridging fluid line 56 includes one or more exchange vents 58. In an orientation-independent configuration, the bridging fluid line 56 is configured within the fluid reservoir tank 50 and the exchange vents 58 are configured on the bridging fluid line 56 such that the exchange vents 58 are not exposed to a gas pocket formed within the fluid reservoir tank 50, regardless of the orientation of the fluid reservoir tank 50. In other words, the exchange vents 58 are always exposed to fluid in the fluid reservoir tank 50.

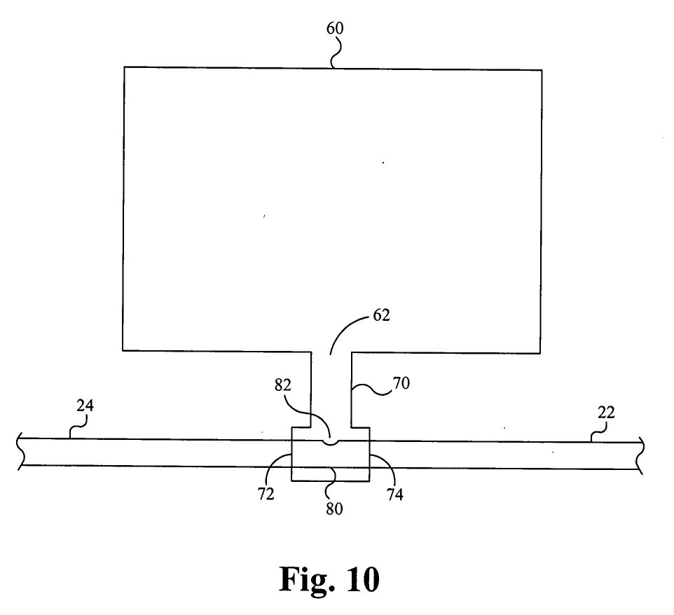

The fluid reservoir tank and bridging fluid line described above are described in relation to the bridging fluid line being configured within the fluid reservoir tank. In alternative configurations, the bridging fluid line is external to the fluid reservoir tank, and the one or more exchange vents in the bridging fluid line are exposed to the fluid within the fluid reservoir tank via an access opening or access port in the fluid reservoir tank. FIG. 10 illustrates a cut-out side view of an exemplary alternative configuration of a fluid reservoir tank 60 coupled to an external bridging fluid line 80. In this exemplary alternative configuration, the fluid reservoir tank 60 includes an opening 62 configured to provide access to the fluid stored within the fluid reservoir tank 60. An extension 70 couples the opening 62 to the bridging fluid line 80 such that the exchange vents 82 of the bridging fluid line 80 are exposed to the fluid from the fluid reservoir tank 60 via the extension 70. The extension 70 includes an inlet 72, which is coupled to the inlet fluid line 24, and an outlet 74, which is coupled to the outlet fluid line 22. In some embodiments, the extension 70 is a separate component from the fluid reservoir tank 60, and the extension 70 is sealed to the fluid reservoir tank 60. In other embodiments, the extension 70 is integrated as part of the fluid reservoir tank 60. Although a single opening 62 is illustrated in FIG. 10, the fluid reservoir tank 60 can be configured with more than one opening 62, each coupled to the bridging fluid line 80 via one or more extensions.

Although the fluid reservoir tanks shown in FIGS. 3, 9, and 10 are rectangular in shape, the fluid reservoir tank can be configured according to any desired shape. This is particularly useful in limited space applications where available space may be of irregular dimensions between or within existing components.

In some embodiments, the fluid reservoir tank is sealed and is used in a closed loop system, which can be used for example in a contamination-free fixed life systems. In other embodiments, the fluid reservoir tank is configured to be opened or includes an access port that allows the tank to be refilled via an extendable system.

While the fluid compensation apparatus is described above for use in a fluid-based cooling system, the fluid compensation apparatus can be used in any unpressurized fluid loop that is sensitive to, or requires freedom of, soluble gas or gas bubbles in the working fluid.

It is apparent to one skilled in the art that the present cooling system is not limited to the components shown in FIG. 2 and alternatively includes other components and devices. For example, although not shown in FIG. 2, the cooling system can also include one or more air movers, such as fans, to direct airflow to the heat rejector.

The present invention has been described in terms of specific embodiments incorporating details to facilitate the understanding of the principles of construction and operation of the invention. Such reference herein to specific embodiments and details thereof is not intended to limit the scope of the claims appended hereto. It will be apparent to those skilled in the art that modifications may be made in the embodiment chosen for illustration without departing from the spirit and scope of the invention.

What is claimed is:

1. A fluid compensation apparatus comprising:
a. a fluid reservoir tank including an inlet port and an outlet port, wherein the fluid reservoir tank is configured to store fluid;
b. an inlet fluid line coupled to the inlet port and configured to input fluid into the inlet port;
c. an outlet fluid line coupled to the outlet port and configured to output fluid from the outlet port; and
d. a bridging fluid line coupling the inlet port to the outlet port, wherein the bridging fluid line is configured to pass input fluid from the inlet port to the outlet port, further wherein the bridging fluid line includes one or more exchange vents, thereby exposing the fluid in the bridging fluid line to the fluid in the fluid reservoir tank, each of the one or more exchange vents is configured to enable gas present in the bridging fluid line to pass into the fluid reservoir tank and to enable fluid in the fluid reservoir tank to pass into the bridging fluid line.

2. The apparatus of claim 1 wherein a size of each of the one or more exchange vents, a surface tension of the fluid in the bridging fluid line, and a fluid flow rate of the fluid in the bridging fluid line are configured to substantially prevent the fluid in the bridging fluid line from passing through the one or more exchange vents.

3. The apparatus of claim 1 wherein a size of each of the one or more exchange vents, a surface tension of the fluid in the bridging fluid line, and a fluid flow rate of the fluid in the bridging fluid line are configured to enable gas present in the bridging fluid line to pass through the one or more exchange vents and into the fluid reservoir tank.

4. The apparatus of claim 1 wherein a size of each of the one or more exchange vents, a surface tension of the fluid in the bridging fluid line, and a fluid flow rate of the fluid in the bridging fluid line are configured to substantially prevent gas accumulated in the fluid reservoir tank from passing through the one or more exchange vents and into the bridging fluid line.

5. The apparatus of claim 1 wherein the fluid reservoir tank is configured such that gas accumulated in the fluid reservoir tank is not exposed to the bridging fluid line.

6. The apparatus of claim 5 wherein the fluid reservoir tank is orientation-independent.

7. The apparatus of claim 5 wherein the fluid reservoir tank is orientation-specific.

8. The apparatus of claim 1 wherein each of the one or more exchange vents comprises a hole, slit, or perforation.

9. The apparatus of claim 1 wherein each of the one or more exchange vents comprises a mesh.

10. The apparatus of claim 1 wherein the gas present in the bridging fluid line comprises gas bubbles or soluble gas.

11. The apparatus of claim 1 wherein the fluid reservoir tank is sealed.

12. The apparatus of claim 1 wherein the fluid reservoir tank is configured to be opened.

13. A fluid compensation system comprising:
a. A fluid compensation apparatus including a fluid reservoir tank and a bridging fluid line, wherein the fluid reservoir tank includes an inlet port and an outlet port, and the fluid reservoir tank is configured to store fluid, further wherein the bridging fluid line couples the inlet port to the outlet port, and the bridging fluid line is configured to pass input fluid from the inlet port to the outlet port, further wherein the bridging fluid line includes one or more exchange vents, thereby exposing the fluid in the bridging fluid line to the fluid in the fluid reservoir tank, each of the one or more exchange vents is configured to enable gas present in the bridging fluid line to pass into the fluid reservoir tank and to enable fluid in the fluid reservoir tank to pass into the bridging fluid line; and
b. a fluid-based cooling loop coupled to the inlet port and to the outlet port of the fluid compensation apparatus, wherein the cooling loop is configured to provide fluid to and from the fluid compensation apparatus.

14. The system of claim 13 wherein the cooling loop comprises one or more heat exchangers and a pump.

15. The system of claim 13 wherein a size of each of the one or more exchange vents, a surface tension of the fluid in the bridging fluid line, and a fluid flow rate of the fluid in the bridging fluid line are configured to substantially prevent the fluid in the bridging fluid line from passing through the one or more exchange vents.

16. The system of claim 13 wherein a size of each of the one or more exchange vents, a surface tension of the fluid in the bridging fluid line, and a fluid flow rate of the fluid in the bridging fluid line are configured to enable gas present in the bridging fluid line to pass through the one or more exchange vents and into the fluid reservoir tank.

17. The system of claim 13 wherein a size of each of the one or more exchange vents, a surface tension of the fluid in the bridging fluid line, and a fluid flow rate of the fluid in the bridging fluid line are configured to substantially prevent gas accumulated in the fluid reservoir tank from passing through the one or more exchange vents and into the bridging fluid line.

18. The system of claim 13 wherein the fluid reservoir tank is configured such that gas accumulated in the fluid reservoir tank is not exposed to the bridging fluid line.

19. The system of claim 18 wherein the fluid reservoir tank is orientation-independent.

20. The system of claim 18 wherein the fluid reservoir tank is orientation-specific.

21. The system of claim 13 wherein each of the one or more exchange vents comprises a hole, slit, or perforation.

22. The system of claim 13 wherein each of the one or more exchange vents comprises a mesh.

23. The system of claim 13 wherein the gas present in the bridging fluid line comprises gas bubbles or soluble gas.

24. The system of claim 13 wherein the fluid reservoir tank is sealed.

25. The system of claim 13 wherein the fluid reservoir tank is configured to be opened.

26. A fluid compensation apparatus comprising:
a. a fluid reservoir tank including an access opening, wherein the fluid reservoir tank is configured to store fluid;
b. an extension coupled to the access opening; and
c. a bridging fluid line coupled to the extension, wherein the bridging fluid line is configured to pass fluid therethrough, further wherein the bridging fluid line includes one or more exchange vents and is coupled to the extension such that the one of more exchange vents are exposed to fluid in the fluid reservoir tank via the extension, each of the one or more exchange vents is configured to enable gas present in the bridging fluid line to pass into the fluid reservoir tank and to enable fluid in the fluid reservoir tank to pass into the bridging fluid line.

27. The apparatus of claim 26 wherein a size of each of the one or more exchange vents, a surface tension of the fluid in the bridging fluid line, and a fluid flow rate of the fluid in the bridging fluid line are configured to substantially prevent the fluid in the bridging fluid line from passing through the one or more exchange vents.

28. The apparatus of claim 26 wherein a size of each of the one or more exchange vents, a surface tension of the fluid in the bridging fluid line, and a fluid flow rate of the fluid in the bridging fluid line are configured to enable gas present in the bridging fluid line to pass through the one or more exchange vents and into the fluid reservoir tank.

29. The apparatus of claim 26 wherein a size of each of the one or more exchange vents, a surface tension of the fluid in the bridging fluid line, and a fluid flow rate of the fluid in the bridging fluid line are configured to substantially prevent gas accumulated in the fluid reservoir tank from passing through the one or more exchange vents and into the bridging fluid line.

30. The apparatus of claim 26 wherein the fluid reservoir tank is configured such that gas accumulated in the fluid reservoir tank is not exposed to the bridging fluid line.

31. The apparatus of claim 26 wherein each of the one or more exchange vents comprises a hole, slit, or perforation.

32. The apparatus of claim 26 wherein each of the one or more exchange vents comprises a mesh.

33. The apparatus of claim 26 wherein the gas present in the bridging fluid line comprises gas bubbles or soluble gas.

34. The apparatus of claim 26 wherein the fluid reservoir tank is sealed.

35. The apparatus of claim 26 wherein the fluid reservoir tank is configured to be opened.

36. The apparatus of claim 26 wherein the fluid reservoir tank includes more than one access opening and the fluid compensation apparatus comprises one or more extensions configured to couple the fluid reservoir tank to the bridging fluid line.
